(19) United States
(12) Patent Application Publication
(10) Pub. No.: US 2006/0160287 A1
(43) Pub. Date: Jul. 20, 2006

(54) Method of fabricating semiconductor device

(75) Inventor: Toshihide Yamaguchi, Kanagawa (JP)

Correspondence Address: SUGHRUE MION, PLLC, 2100 PENNSYLVANIA AVENUE, N.W., SUITE 800, WASHINGTON, DC, 20037, US

(73) Assignee: NEC ELECTRONICS CORPORATION

(21) Appl. No.: 11/333,329

(22) Filed: Jan. 18, 2006

(30) Foreign Application Priority Data
Jan. 19, 2005 (JP) 2005-012163

(51) Int. Cl. H01L 21/337

(52) U.S. Cl. 438/193

(57) ABSTRACT

There has been a problem of damaging a diffusion layer 4 occasionally in etching of a nitride film 5 in a wide gate pitch P1 region. First, a plurality of diffusion layers 4, gates 2 and sidewalls 3 are formed on a silicon substrate 1, so as to be adjacent to each other. Next, a nitride film 5 is stacked on the diffusion layers 4, the gates 2 and the sidewalls 3, so that the surface of the film reaches a level higher than the top surface of the gates 2, and so as to fill up the entire portion of gaps in a narrow gate pitch P region. Next, the surface of the nitride film 5 is planarized, and further on the nitride film 6, an insulating oxide film 6 is stacked. Contact holes 7 are then formed, and a connection plug 8 is formed in each of the holes.

This application is based on Japanese patent application No. 2005-012163 the content of which is incorporated hereinto by reference.

### BACKGROUND

1. Technical Field

The present invention relates to a method of fabricating a semiconductor device having contact holes formed between adjacent gates.

2. Related Art

There has been known a method of fabricating a semiconductor device, in which a nitride film is formed on a silicon substrate, a trench is formed by etching the nitride film, an oxide film for a gate is formed on the bottom portion of the trench, a metal film is formed so as to cover the trench, and a source electrode and a drain electrode are formed in the silicon substrate by ion implantation (see Japanese Laid-Open Patent Publication No. 10-270688, for example).

There has also been known an integrated circuit having, as shown in FIG. 2A, a nitride film (direct nitride film) formed on the diffusion layers and the gates.

The integrated circuit shown in FIG. 2A is fabricated as described below. The gates 2, sidewalls 3 and the diffusion layers 4 are formed on a silicon substrate 1, and further thereon the nitride film 5 is stacked. On the nitride film 5, an insulating oxide film 6 is stacked, and contact holes 7 are formed in the nitride film 5 and the insulating oxide film 6 by etching these films. In each of the contact holes 7, a connection plug 8 is formed, and a copper interconnection 9 is formed on the connection plug 8. The nitride film 5 has a function as an etching stopper film for the insulating oxide film 6 right above the diffusion layers 4 in the process of etching forming the contact holes, and also has a function of controlling stress exerted on NMOS transistors to thereby improve their performances.

In general, shrinkage of the scale of transistor unconditionally results in reduction in the gate pitch (distance between the centers of the gates). More specifically, in the 90-nm-gate-length generation device before being shrunk in the scale, as shown in FIG. 3A, a portion having a minimum gate pitch has a narrow gate pitch P of approximately 380 nm, and has an end-to-end distance between the sidewalls of approximately 140 nm. In contrast, the 65-nm-gate-length generation device shown in FIG. 3B is shrunk in the narrow gate pitch P to as small as approximately 300 nm, and in the end-to-end distance between the sidewalls of approximately 80 nm.

The nitride film 5 in the integrated circuit shown in FIG. 2A has a uniform thickness T (50 nm or around, in consideration of NMOS transistor performance) in the contact portion with the diffusion layers in all portions between every adjacent gates, that is, in the narrow gate pitch P region and in a wide gate pitch P1 region having a wider gate pitch, and this allows the nitride film 5 to fully exhibit a function as an etching stopper film for the insulating oxide film 6 when the contact holes 7 are formed therein.

However, in the contact portions with the diffusion layers in the narrow gate pitch P region of 80 nm or around as shown in FIG. 3B, the nitride film 5 having a thickness T of as thick as exceeding 40 nm fills up the gaps between the sidewalls 3, 3. The thickness of thus filled-up nitride film 5a is larger by several times than the thickness of the nitride film 5 in the wide gate pitch P1 region, and causes a large difference in the etching time of the nitride film 5. It is therefore anticipated that the diffusion layers 4 in the wide gate pitch P1 region having thereon only a small thickness of the nitride film may be damaged by over-etching.

Any effort of avoiding this problem, such as stacking the nitride film 5 only to a thickness so as not to fill up the gaps between the adjacent gates in the narrow gate pitch P region results in thinning of the nitride film 5. This makes it difficult to allow the nitride film 5 to function as a stress control film, and to improve performances of the NMOS transistor to a desired specification level.

### SUMMARY OF THE INVENTION

According to the present invention, there is provided a method of fabricating a semiconductor device, which include:

forming, on one surface of a semiconductor substrate, MOSFETs each comprising diffusion layers, a gate electrode and sidewall insulating films;

forming a first insulating film which contains silicon and nitrogen, so as to fill up the entire portion of gaps in a narrow pitch region of the gates of the MOSFETs, and so that the surface of the film reaches a level higher than the top surface of the gate electrode;

planarizing the surface of the first insulating film;

stacking a second insulating film on the first insulating film;

forming contact holes by selectively etching the second insulating film and the first insulating film, so as to respectively reach the diffusion layers;

forming a connection plug in each of the contact holes by filling therein an electro-conductive film; and

forming an interconnection layer on the second insulating film so as to be connected with the connection plug.

According to the method of fabricating a semiconductor device of the present invention, the nitride film is formed so as to reach a level higher than the gate height, then planarized typically by the CMP process, the insulating oxide film is stacked thereon, and the films are etched in order to form the contact holes, so that the nitride film can be stacked a uniform thickness over the entire portion of the diffusion layer. Therefore, it is possible to avoid over-etching of the diffusion layers during the etching for forming thereon the contact holes, ascribable to non-uniformity in the thickness of the nitride film, and to obtain the thickness of the nitride film enough for allowing it to function as a stress control film.

The present invention is more effective if a minimum gate pitch is set to 100 nm or below.

The present invention can avoid the over-etching by making the thickness of the nitride film uniform over the entire region on the diffusion layers, and can thereby improve performances of the semiconductor device.

### BRIEF DESCRIPTION OF THE DRAWINGS

The above and other objects, advantages and features of the present invention will be more apparent from the following description taken in conjunction with the accompanying drawings, in which:

FIGS. 1A to 1E are drawings showing process steps of fabricating a semiconductor device according to one embodiment of the present invention;

FIGS. 2A and 2B are sectional views showing a conventional semiconductor device having narrow gate pitches of different sizes; and

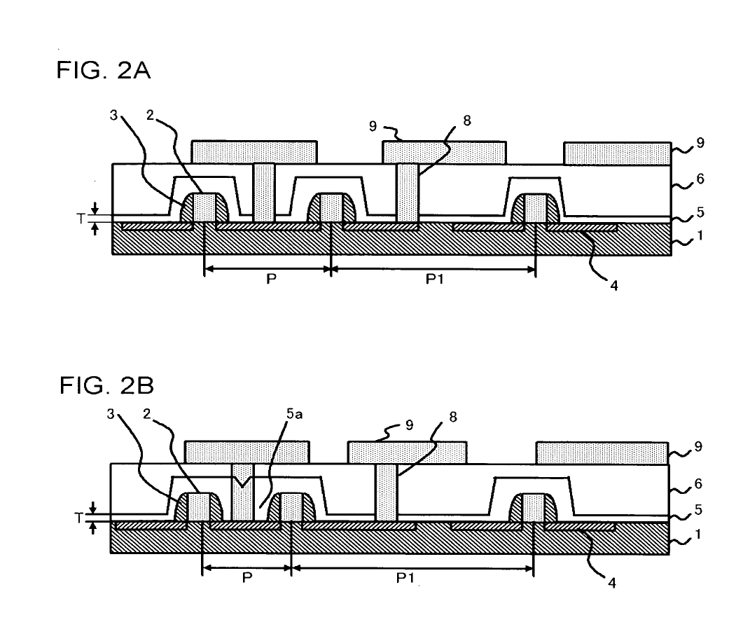

FIGS. 3A and 3B are sectional views showing the gate portion having narrow gate pitches of different sizes.

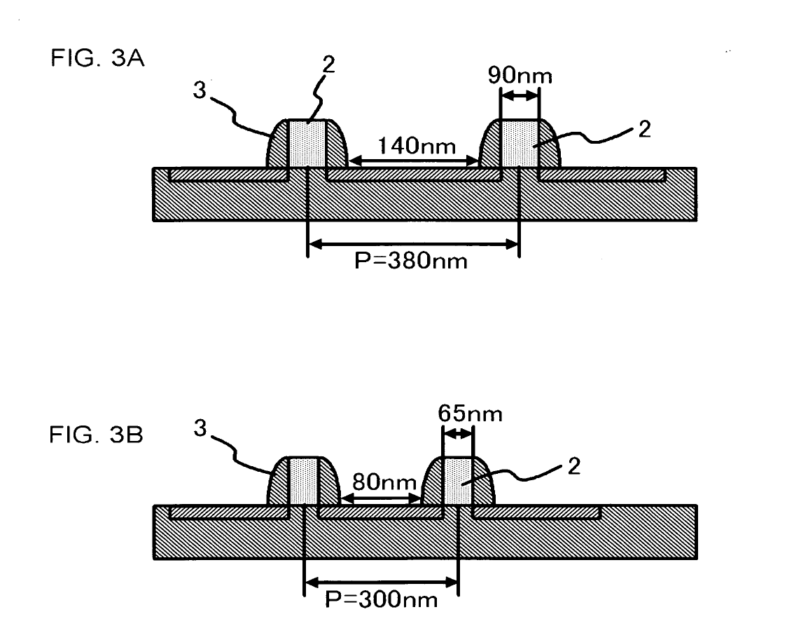

### DETAILED DESCRIPTION

The invention will be now described herein with reference to illustrative embodiments. Those skilled in the art will recognize that many alternative embodiments can be accomplished using the teachings of the present invention and that the invention is not limited to the embodiments illustrated for explanatory purposes.

Paragraphs below will describe an embodiment of the present invention referring to the attached drawings.

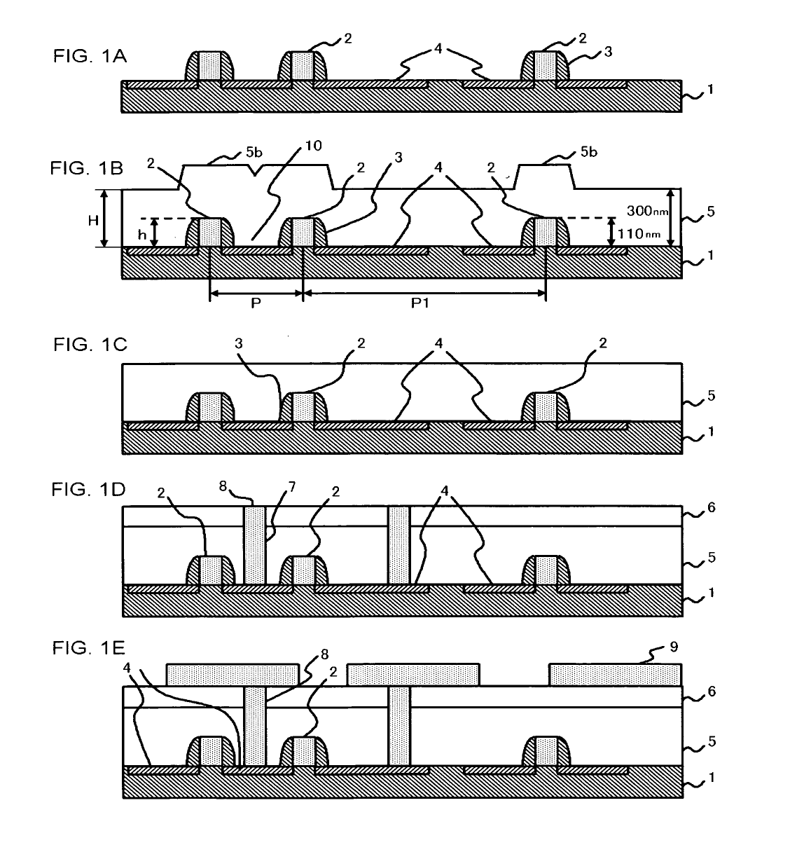

First, as shown in FIG. 1A, a plurality of MOSFETs are formed on one surface of the semiconductor substrate. More specifically, gates 2 and sidewalls 3 are formed on a semiconductor substrate 1 made of silicon, and diffusion layers 4 (source and drain regions) are formed by ion implantation. A silicide film is then formed on the surface of the gates 2 and the diffusion layers 4.

Approximate dimensions of the individual portions are as given below:
gate length=65 nm;
narrow gate pitch P=300 nm; and
distance between sidewalls 3, 3 of adjacent MOSFETs=80 nm.

Next, a direct nitride film 5 (silicon nitride) is formed, so as to fill up the entire portion of gaps between the adjacent gates of the MOSFETs, and so that the surface of the film reaches a level higher than the top surface of the gates 2. The CVD process was adopted as a method of forming the film in this embodiment. The direct nitride film 5 is formed to a thickness H (300 nm, for example) larger than the height h (approximately 110 nm, for example) of the gates 2, even in the portion thereof having the smallest thickness. The direct nitride film 5 goes into all gaps between every adjacent gates, to thereby form the filled-up portion 10 of the direct nitride film 5. At the portion over the gates 2, projected portions 5b having a predetermined height above the top surface of the gates 2 are formed. The portion of the direct nitride film 5 having the projected portions 5b formed therein consequently has a thickness larger than that of the other portions.

Next, as shown in FIG. 1C, the surface of the direct nitride film 5 is planarized typically by the CMP process.

Next, as shown in FIG. 1D, a silicon oxide film 6 is stacked on the direct nitride film 5. The silicon oxide film 6 and the direct nitride film 5 are then selectively etched in this order, to thereby form contact holes 7 which reach the diffusion layers 4 (source and drain regions).

A barrier metal film, not shown, is formed therein, and a connection plug 8 composed of tungsten is formed in each of the contact holes 7 by the damascene process.

Finally, as shown in FIG. 1E, a copper interconnection layer 9 is stacked on the silicon oxide film 6.

Effects of the method of fabrication described above in the embodiment will be explained.

In the etching process forming the contact holes shown in FIG. 1D, the direct nitride film 5 functions as a stopper against the etching for forming the contact holes. The direct nitride film 5 is formed so as to fill up the entire portion of the gaps between every adjacent gates, and therefore has a uniform thickness both in the narrow gate pitch P region and in the wide gate pitch P1 region. The method of fabrication of this embodiment makes it possible to avoid the over-etching ascribable to non-uniformity in the thickness of the nitride film in the conventional process.

The method of fabrication of this embodiment can form the direct nitride film 5 with a uniform thickness. This makes it possible to improve the stress controllability, and to obtain desired NMOS characteristics as designed. This effect becomes more distinctive if a minimum gate pitch is set to 100 nm or below.

It is apparent that the present invention is not limited to the above embodiments, that may be modified and changed without departing from the scope and spirit of the invention.

What is claimed is:

1. A method of fabricating a semiconductor device comprising:
forming, on one surface of a semiconductor substrate, MOSFETs each comprising diffusion layers, a gate electrode and sidewall insulating films;
forming a first insulating film which contains silicon and nitrogen, so as to fill up the entire portion of gaps in a narrow pitch region of the gates of said MOSFETs, and so that the surface of the film reaches a level higher than the top surface of the gate electrode;
planarizing the surface of said first insulating film;
stacking a second insulating film on said first insulating film;
forming contact holes by selectively etching said second insulating film and said first insulating film, so as to respectively reach said diffusion layers;
forming a connection plug in each of said contact holes by filling therein an electro-conductive film; and
forming an interconnection layer on said second insulating film so as to be connected with said connection plug.

2. A method of fabricating a semiconductor device as claimed in claim 1, wherein a minimum pitch of the adjacent gates is 100 nm or less.
